(19) United States
(12) Patent Application Publication
(10) Pub. No.: US 2020/0066822 A1
(43) Pub. Date: Feb. 27, 2020

(54) DISPLAY DEVICE, MANUFACTURING METHOD FOR DISPLAY DEVICE, AND MANUFACTURING DEVICE FOR DISPLAY DEVICE

(71) Applicant: Sharp Kabushiki Kaisha, Sakai City, Osaka (JP)

(72) Inventors: Takao SAITOH, Sakai City (JP); Masaki YAMANAKA, Sakai City (JP); Yohsuke KANZAKI, Sakai City (JP); Seiji KANEKO, Sakai City (JP); Masahiko MIWA, Sakai City (JP)

(21) Appl. No.: 16/466,365

(22) PCT Filed: Jul. 28, 2017
(86) PCT No.: PCT/JP2017/027479

§ 371 Date: Jun. 4, 2019

(51) Int. Cl. H01L 27/32

(52) U.S. Cl. CPC H01L 27/3276; H01L 27/3262

(57) ABSTRACT

A display device including a resin layer, a TFT layer being an upper layer with respect to the resin layer, and a light-emitting element layer being an upper layer with respect to the TFT layer, in which a bending section is provided on a peripheral edge, includes a terminal wiring line that passes through the bending section and is connected to a terminal, and an auxiliary wiring line, and the terminal wiring line includes a first wiring line and a second wiring line that are positioned on both sides of the bending section, and a third wiring line that passes through the bending section and is electrically connected with each of the first wiring line and the second wiring line, and the auxiliary wiring line is superimposed on the third wiring line via a flexible insulating film in the bending section.

### TECHNICAL FIELD

The disclosure relates to a display device.

### BACKGROUND ART

PTL 1 discloses configuration in which a peripheral area of a display device is bent.

### CITATION LIST

### Patent Literature

PTL 1: JP 2016-170266 A (published on Sep. 23, 2016)

### SUMMARY

### Technical Problem

When a bending section is formed in the peripheral edge of the display device, a terminal wiring line passing through the bending section might be broken.

### Solution to Problem

A display device according to a first aspect of the disclosure includes a resin layer, a TFT layer being an upper layer with respect to the resin layer, and a light-emitting element layer being an upper layer with respect to the TFT layer, a bending section being provided on a peripheral edge, includes at least one terminal wiring line configured to pass through the bending section and be connected to a terminal, and at least one auxiliary wiring line, wherein the at least one terminal wiring line includes a first wiring line and a second wiring line configured to be positioned on both sides of the bending section, a third wiring line configured to pass through the bending section and be electrically connected with each of the first wiring line and the second wiring line, and the at least one auxiliary wiring line is superimposed on the third wiring line via a flexible insulating film.

### Advantageous Effects of Disclosure

According to a first aspect of the disclosure, breaks of the terminal wiring line passing through the bending section can be corrected.

### BRIEF DESCRIPTION OF DRAWINGS

FIG. 1 is a flowchart illustrating an example of a manufacturing method of a display device.

FIG. 2 is a cross-sectional view illustrating a configuration example of a display section of the display device.

FIG. 3 is a plan view illustrating a configuration example of the display device.

FIGS. 4A to 4C are views illustrating configuration of a non-display area of a first embodiment; FIG. 4A is a top view, FIG. 4B is a cross-sectional view taken along line A-A′, and FIG. 4C is a cross-sectional view taken along line B-B′.

FIG. 5 is a cross-sectional view illustrating configuration of the bending of a non-display area of the display device.

FIG. 6 is a flowchart illustrating an example of the formation of a TFT layer of the first embodiment.

FIGS. 7A to 7C are views illustrating an example of correction of a broken line in the first embodiment; FIG. 7A is a top view, FIG. 7B is a cross-sectional view taken along line A-A′, and FIG. 7C is a cross-sectional view of a bending section.

FIG. 8 is a block diagram illustrating configuration of a display device manufacturing apparatus.

FIGS. 9A to 9C are views illustrating configuration of a non-display area of a second embodiment; FIG. 9A is a top view, FIG. 9B is a cross-sectional view taken along line A-A′, and FIG. 9C is a cross-sectional view taken along line B-B′.

FIG. 10 is a cross-sectional view illustrating configuration of the bending of the non-display area of the display device.

FIG. 11 is a flowchart illustrating an example of the formation of a TFT layer of the second embodiment.

FIGS. 12A to 12C are views illustrating an example of correction of a broken line in the second embodiment; FIG. 12A is a top view, FIG. 12B is a cross-sectional view taken along line A-A′, and FIG. 12C is a cross-sectional view of a bending section.

FIGS. 13A and 13B are cross-sectional views illustrating configuration of a non-display area of a third embodiment.

FIG. 14 is a flowchart illustrating an example of the formation of a TFT layer of the third embodiment.

FIGS. 15A and 15B are views illustrating an example of correction of a broken line in the third embodiment.

### DESCRIPTION OF EMBODIMENTS

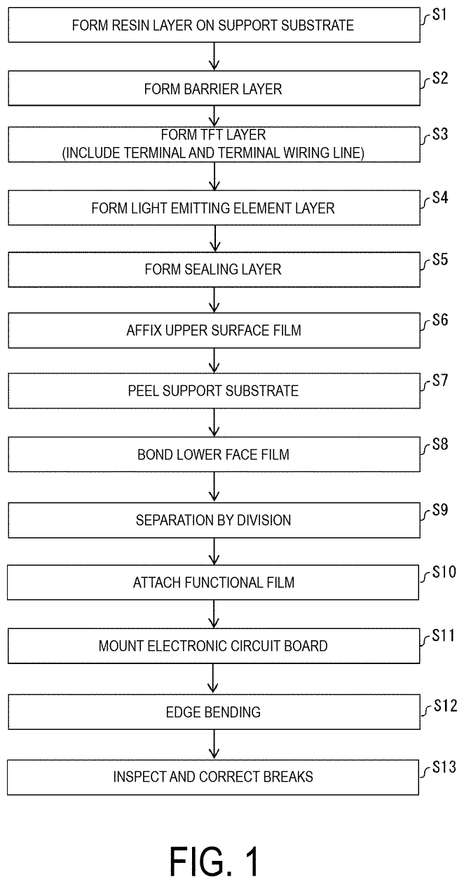

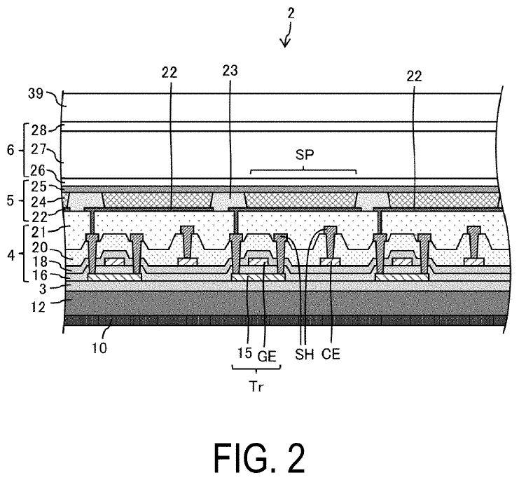

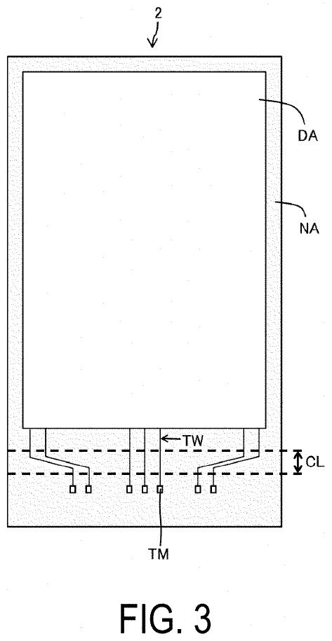

FIG. 1 is a flowchart illustrating an example of a manufacturing method of a display device. FIG. 2 is a cross-sectional view illustrating a configuration example of a display section of the display device. FIG. 3 is a plan view illustrating a configuration example of the display device. Hereinafter, “same layer” means being formed of an identical material in an identical process, and “lower layer” means being formed in a prior process with respect to that of a layer to be compared, and “upper layer” means being formed in a posterior process with respect to that of a layer to be compared.

When a flexible display device is manufactured, as illustrated in FIGS. 1 to 3, first, a resin layer 12 is formed on a transparent support substrate (for example, a mother glass substrate) (Step S1). Next, a barrier layer 3 is formed (Step S2). Next, a TFT layer 4 including terminals TM and terminal wiring lines TW is formed (Step S3). Next, a light-emitting element layer (for example, an OLED element layer) 5 of a top-emitting type is formed (Step S4). Next, a sealing layer 6 is formed (Step S5). Next, an upper face film is bonded to the sealing layer 6 (Step S6).

Next, the lower face of the resin layer 12 is irradiated with laser light through the support substrate, thereby reducing bonding strength between the support substrate and the resin layer 12 and peeling the support substrate off the resin layer 12 (Step S7). Next, a lower face film 10 is bonded to the lower face of the base layer 12 (Step S8). Next, a layered body including the lower face film 10, the resin layer 12, the barrier layer 3, the TFT layer 4, the light-emitting element layer 5, and the sealing layer 6 is divided into a plurality of individual pieces (Step S9). Next, a function film 39 is bonded to the acquired individual pieces (Step S10). Next, an electronic circuit board (for example, IC chip) is mounted on a terminal for external connection (Step S11). Next, an edge bending (process for bending a bending section CL in FIG. 3 by 180 degrees) is applied, thereby forming a display device 2 (Step S12). Next, inspection for breaks is performed, and in a case where a break is present, correction is made (Step S13). Note that each of the above-described steps is performed by a display device manufacturing apparatus described later.

Examples of the material of the resin layer 12 include polyimide, epoxy, and polyamide. Examples of the material of the lower face film 10 include polyethylene terephthalate (PET).

The barrier layer 3 is a layer that inhibits moisture or impurities from reaching the TFT layer 4 or the light-emitting element layer 5 when the display device is being used, and can be constituted by a silicon oxide film, a silicon nitride film, or a silicon oxynitride film, or by a layered film of these, formed using CVD, for example.

The TFT layer 4 includes a semiconductor film 15, an inorganic insulating film 16 (a gate insulating film) that is formed above the semiconductor film 15, a gate electrode GE that is formed above the inorganic film 16, an inorganic insulating film 18 that is formed above the gate electrode GE, capacitance wiring line CE that is formed above the inorganic insulating film 18, an inorganic insulating film 20 that is formed above the capacitance wiring line CE, source wiring lines SH and terminals TM that are formed above the inorganic insulating film 20, and a flattening film 21 that is formed above the source wiring lines SH and the terminals TM.

A thin film transistor (TFT) Tr is configured to include the semiconductor film 15, the inorganic insulating film 16 (the gate insulating film), and the gate electrode GE.

In a non-display region NA of the TFT layer 4, the terminals TM that are used for connection with an electronic circuit board, such as an IC chip and an FPC, and the terminal wiring lines TW (described later in detail) that connect the terminals TM with wiring lines in an active area DA, and the like are formed.

The semiconductor film 15 is formed of, for example, low-temperature polysilicon (LTPS) or an oxide semiconductor. Note that, FIG. 2 illustrates the TFT that has a top gate structure in which the semiconductor film 15 is the channel, but the TFT may have a bottom gate structure (when the TFT channel is the oxide semiconductor, for example).

The gate electrode GE, a capacitance electrode CE, the source wiring line SH, the terminal wiring line TW, and the terminals TM are each constituted by a single-layer metal film or a layered metal film including at least one of aluminum (Al), tungsten (W), molybdenum (Mo), tantalum (Ta), chromium (Cr), titanium (Ti), and copper (Cu), for example.

The inorganic insulating films 16, 18, and 20 can be constituted by a silicon oxide (SiOx) film or a silicon nitride (SiNx) film, or a layered film of these, formed using CVD, for example.

The flattening film (interlayer insulating film) 21 can be constituted, for example, by a coatable photosensitive organic material, such as a polyimide or an acrylic.

The light-emitting element layer (for example, an organic light-emitting diode layer) 5 includes an anode 22 that is formed in a layer above the flattening film 21, a bank (electrode edge cover) that covers the edge of the anode 22, an electroluminescence (EL) layer 24 that is formed in a layer above the anode 22, a cathode 25 that is formed in a layer above the EL layer 24, and for each subpixel, a light-emitting element (for example, OLED: an organic light-emitting diode) that includes the insular anode 22, the EL layer 24, and the cathode 25, and a subpixel circuit for driving this are provided. The bank 23 can be formed of, for example, a coatable photosensitive organic material such as polyimide or acrylic, for example.

For example, the organic EL layer 24 is formed by layering a hole injection layer, a hole transport layer, a light-emitting layer, an electron transport layer, and an electron injection layer in the order from the lower layer side. The light-emitting layer is formed for each subpixel in an insular shape by a vapor deposition method or an ink-jet method, but other layers can be provided as a flat common layer. In addition, it is possible to have configuration in which one or more layers out of the hole injection layer, the hole transport layer, the electron transport layer, and the electron injection layer are not formed.

The anode (anode) 22 is formed by layering indium tin oxide (ITO) and Ag (silver) or an alloy containing Ag, for example, and has light reflectivity (to be described below in more detail). The cathode 25 can be constituted by a light-transmissive conductive material such as indium tin oxide (ITO) and indium zinc oxide (IZO).

In the case that the light-emitting element layer 5 is the OLED layer, positive holes and electrons are recombined inside the EL layer 24 by a drive current between the anode 22 and the cathode 25, and light is emitted as a result of excitons that are generated by the recombination falling into a ground state. Since the cathode 25 is light-transmissive and the anode 22 is light-reflective, the light emitted from the EL layer 24 travels upward and results in top emission.

The light-emitting element layer 5 is not limited to OLED element configurations, and may be an inorganic light-emitting diode or a quantum dot light-emitting diode.

The sealing layer 6 is light-transmissive, and includes a first inorganic sealing film 26 that covers the cathode 25, an organic sealing film 27 that is formed above the first inorganic sealing film 26, and a second inorganic sealing film 28 that covers the organic sealing film 27. The sealing layer 6 covering the light-emitting element layer 5 prevents foreign matters, such as water and oxygen, from infiltrating into the light-emitting element layer 5.

The first inorganic sealing film 26 and the second inorganic sealing film 28 can be each constituted by a silicon oxide film, a silicon nitride film, or a silicon oxynitride film, or by a layered film of these, formed using CVD. The organic sealing film 27 is thicker than the first inorganic sealing film 26 and the second inorganic sealing film 28, is a light-transmissive organic film, and can be constituted by a coatable photosensitive organic material such as a polyimide or an acrylic.

After the support substrate has been peeled off, the lower face film 10 is bonded to the lower face of the resin layer 12, thereby achieving a display device having excellent flexibility, and examples of a material of the lower face film 10 include PET and the like. The function film 39 includes, for example, an optical compensation function, a touch sensor function, a protection function, and the like.

Thereinbefore, the explanation has been given for a case of manufacturing the flexible display device, but when a non-flexible display device is manufactured, replacement of the substrate and the like is not required, and thus the processing may proceed from Step S5 to Step S9 illustrated in FIG. 1, for example.

### First Embodiment

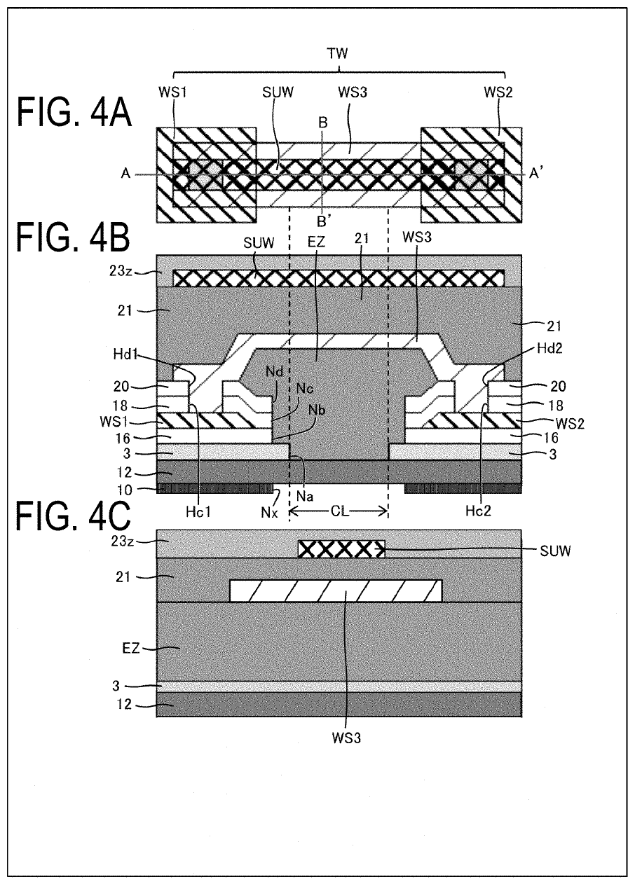

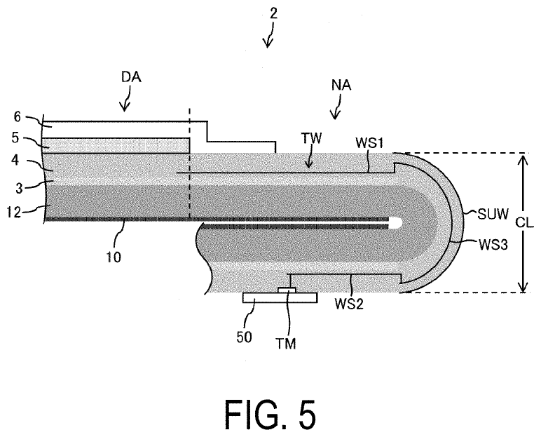

FIGS. 4A to 4C are views illustrating a peripheral edge of the display device of a first embodiment; FIG. 4A is a top view, FIG. 4B is a cross-sectional view taken along line A-A′, and FIG. 4C is a cross-sectional view taken along line B-B′. FIG. 5 is a cross-sectional view illustrating an example of the bending of a non-display area of the display device.

As illustrated in FIGS. 4A to 5, the peripheral edge (non-display area) NA of the display device 2 includes the lower face film 10, the resin layer 12, the barrier layer 3, the inorganic insulating films 16, 18, and 20, a reinforcing film EZ, the flattering film 21 that serves as an underlayer of the light-emitting element layer 5, the terminals TM, the terminal wiring lines TW connecting to the terminals TM, and auxiliary wiring lines SUW, and the bending section CL is provided on the peripheral edge NA.

The terminal TM is connected to the display area DA by the terminal wiring line TW passing through the bending section CL. The reinforcing film EZ, for example, can be constituted by a coatable photosensitive organic material, such as a polyimide or an acrylic and formed on an upper layer with respect to the inorganic insulating film 20 and on a lower layer with respect to the flattening film 21.

As illustrated in FIG. 5, the display device 2 is bent by 180 degrees at the bending section CL, thereby connecting the terminal TM disposed on the lower face side and an electronic circuit board 50 (IC chip or flexible printed circuit board).

As illustrated in FIGS. 4A to 4C, the lower face film 10, the barrier layer 3, and the inorganic insulating films 16, 18, and 20 are penetrated in the bending section CL. Specifically, a penetration section Nx is formed in the lower face film 10, a penetration section Na is formed in the barrier layer 3, a penetration section Nb is formed in the inorganic insulating film 16, a penetration section Nc is formed in the inorganic insulating film 18, a penetration section Nd is formed in the inorganic insulating film 20, and in a planar view, the penetration sections Nx, Nb, Nc, and Nd are aligned, and the penetration section Na aligned to the bending section CL is positioned on the inside of the penetration sections Nx, Nb, Nc, and Nd. The reinforcing film EZ is provided in a space formed by the penetration sections Na, Nb, Nc, and Nd.

The terminal wiring line TW includes a first wiring line WS1 and a second wiring line WS2 positioned on both sides of the bending section CL, and a third wiring line WS3 that passes through the bending section CL and electrically connects to each of the first wiring line WS1 and the second wiring line WS2. The auxiliary wiring line SUW is superimposed on the third wiring line WS3 via the flattening film 21 (flexible insulating film) in the bending section CL.

Specifically, the first wiring line WS1 and the second wiring line WS2 are formed in the same layer as that of the gate electrodes GE (see FIG. 2) included in the TFT layer 4. The third wiring line WS3 is formed in the same layer as that of the source wiring lines SH (see FIG. 2) and the terminals TM included in the TFT layer 4, and has a configuration in which an Al film is sandwiched between two Ti films, for example. The auxiliary wiring line SUW is formed in the same layer as that of the anode 22 of the light-emitting element layer 5, and for example, has a configuration in which an Ag film is sandwiched between two ITO films. The third wiring line WS3 and the auxiliary wiring line SUW extend in the same direction, and the third wiring line WS3 is wider in width than the auxiliary wiring line SUW, and in a planar view, the auxiliary wiring line SUW is positioned in the edge of the third wiring line WS3.

The third wiring line WS3 is led from one side of the bending section CL to the other side of the bending section CL over the reinforcing film EZ, and sandwiched between the reinforcing film EZ and the flattening film 21 in the bending section CL. The auxiliary wiring line SUW passes on the flattening film 21 and is sandwiched between the flattening film 21 and an organic insulating film 23z formed in the same layer as that of the bank 23 (electrode edge cover: see FIG. 2) in the bending section CL. The reinforcing film EZ, the flattening film 21, and the organic insulating film 23z may be formed of the same organic material (e.g., polyimide).

The one end of the third wiring line WS3 is connected to the first wiring line WS1 by a contact hole Hc1 formed in the inorganic insulating film 18 and a contact hole Hd1 formed in the inorganic insulating film 20 and communicating with the contact hole Hc1, and the other end of the third wiring line WS3 is connected to the second wiring line WS2 by a contact hole Hc2 formed in the inorganic insulating film 18 and a contact hole Hd2 formed in the inorganic insulating film 20 and communicating with the contact hole Hc2.

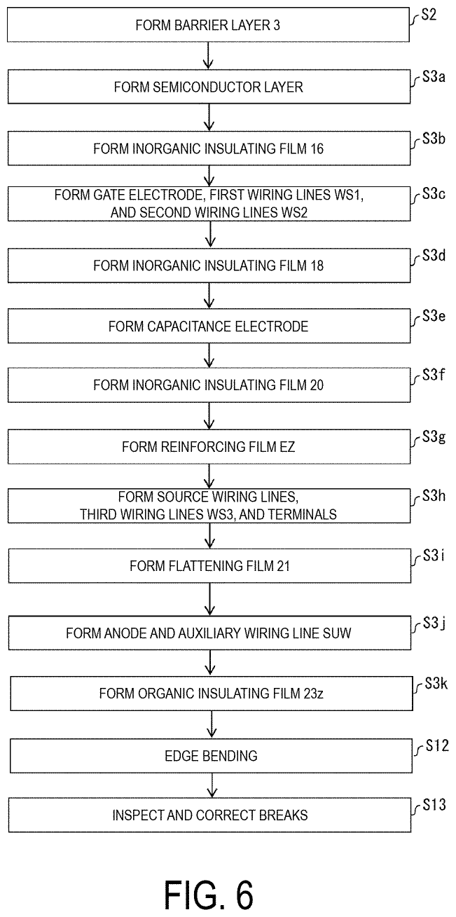

FIG. 6 is a flowchart illustrating an example of the formation of a TFT layer of the first embodiment. Subsequent to Step S1 in FIG. 1, the barrier layer 3 is formed at Step S2. At the next Step S3a, the semiconductor film 15 (see FIG. 2) is formed. At the next Step S3b, the inorganic insulating film 16 is formed. At the next Step S3c, the gate electrode, the first wiring lines WS1, and the second wiring lines WS2 are formed. At the next Step S3d, the inorganic insulating film 18 is formed. At the next Step S3e, the capacitance electrode CE (see FIG. 2) is formed. At the next Step S3f, the inorganic insulating film 20 is formed. At the next Step S3g, the reinforcing film EZ is formed. At the next Step S3h, the source wiring lines SH (see FIG. 2), the third wiring lines WS3, and the terminals TM are formed. At the next Step S3i, the flattening film 21 is formed. At the next Step S3j, the anode 22 (see FIG. 2) and the auxiliary wiring lines SUW are formed. At the next Step S3k, the organic insulating film 23z formed in the same layer as that of the bank 23 is formed. Note that the formation (patterning) of the penetration sections Nb, Nc and Nd may be performed in successive processes. Subsequently, as illustrated in FIG. 1, an edge bending is performed at Step S10, and inspection for breaks of the terminal wiring line is performed at Step S11.

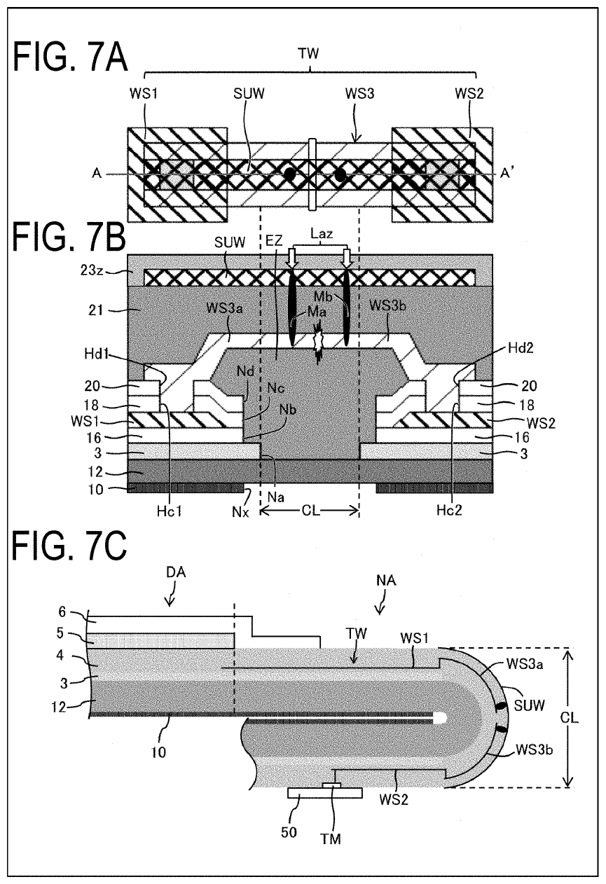

FIGS. 7A to 7C are views illustrating an example of correction of a broken line in the first embodiment; FIG. 7A is a top view, FIG. 7B is a cross-sectional view taken along line A-A′, and FIG. 7C is a cross-sectional view of a bending section. When breaks are found at Step S11, and the third wiring line WS3 is divided by the breaks into a front portion WS3a and a rear portion WS3b, as illustrated in FIGS. 7A to 7C, the front portion WS3a is connected to the auxiliary wiring line SUW by a conductor Ma penetrating the flattening film 21, and the rear portion WS3b is connected to the auxiliary wiring line SUW by a conductor Mb penetrating the flattening film 21. The conductors Ma and Mb are formed by melting the two sections of the auxiliary wiring line SUW (sections corresponding to both sides of the breaks in a planar view) by the irradiation of laser Laz. Note that each of the front portion WS3a and the rear portion WS3b may be melt by the irradiation of laser.

In the first embodiment, as illustrated in FIGS. 7A to 7C, the front portion WS3a and the rear portion WS3b that occurs due to the breaks of the third wiring line WS3 can be connected by the auxiliary wiring line SUW, so that it is possible to correct the terminal wiring line TW. That is, in the display device 2, the terminal wiring line TW that has been corrected (includes a break) is electrically connected to the auxiliary wiring line SUW, and the terminal wiring line TW that is not corrected (includes no break) is not electrically connected to the auxiliary wiring line SUW.

In addition, the barrier layer 3 and the inorganic insulating films 16, 18, and 20 (which are closely-packed and solid) formed using CVD are penetrated in the bending section CL, so that stress in bending the bending section CL is reduced, and the breaks of the third wiring line WS3 and the auxiliary wiring line SUW are unlikely to occur.

In addition, each of the third wiring line WS3 and the auxiliary wiring line SUW in the bending section CL is sandwiched between organic materials formed of a coating that is high in flexibility compared to the inorganic materials formed using CVD, so that the breaks of the third wiring line WS3 and the auxiliary wiring line SUW are unlikely to occur.

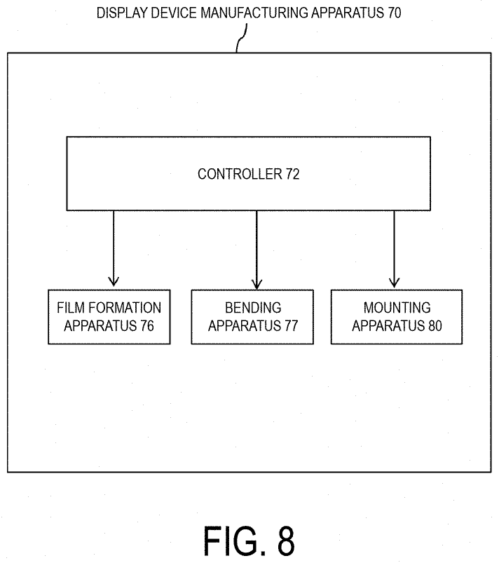

FIG. 8 is a block diagram illustrating configuration of a display device manufacturing apparatus. As illustrated in FIG. 8, a display device manufacturing apparatus 70 includes a film formation apparatus 76, a bending apparatus 77, a mounting apparatus 80, and a controller 72 for controlling these apparatuses, and the film formation apparatus 76 performs Steps S2 to S3k in FIG. 6, and the bending apparatus 77 performs Step S10, and the mounting apparatus 80 performs Step S11.

### Second Embodiment

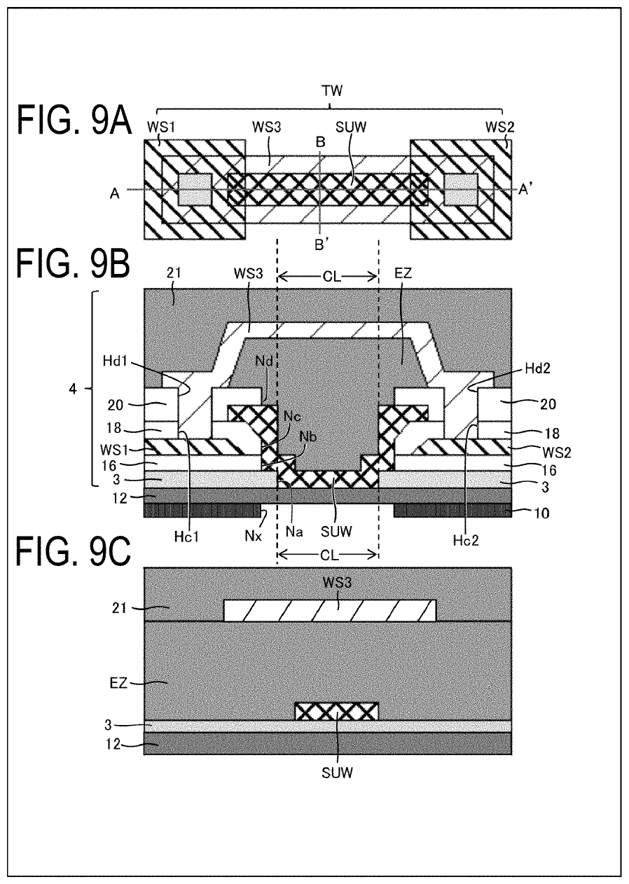

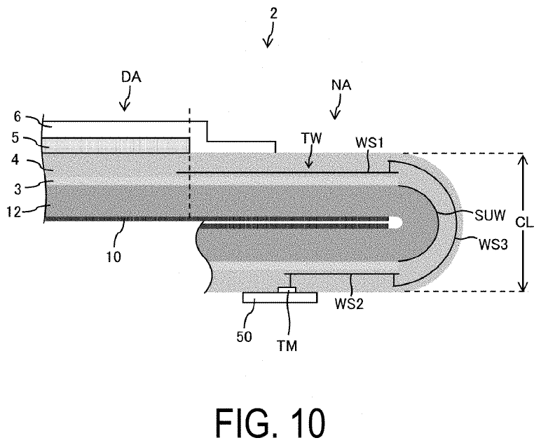

In the first embodiment, the auxiliary wiring line SUW is provided in the same layer as that of the anode, but not limited to this. FIGS. 9A to 9C are views illustrating a peripheral edge of the display device of a second embodiment; FIG. 9A is a top view, FIG. 9B is a cross-sectional view taken along line A-A′, and FIG. 9C is a cross-sectional view taken along line B-B′. FIG. 10 is a cross-sectional view illustrating an example of the bending of the non-display area of the display device.

As illustrated in FIGS. 9A to 10, the terminal wiring line TW includes a first wiring line WS1 and a second wiring line WS2 positioned on both sides of the bending section CL, and a third wiring line WS3 that passes through the bending section CL and electrically connects to each of the first wiring line WS1 and the second wiring line WS2. The auxiliary wiring line SUW is superimposed on the third wiring line WS3 via the reinforcing film EZ (flexible insulating film) in the bending section CL.

Specifically, the first wiring line WS1 and the second wiring line WS2 are formed in the same layer as that of the gate electrodes GE (see FIG. 2) included in the TFT layer 4. The third wiring line WS3 is formed in the same layer as that of the source wiring lines SH (see FIG. 2) and the terminals TM included in the TFT layer 4, and has configuration in which an Al film is sandwiched between two Ti films, for example. The auxiliary wiring line SUW is formed in the same layer as that of the capacitance electrode CE of the TFT layer 4. The third wiring line WS3 and the auxiliary wiring line SUW extend in the same direction, and the third wiring line WS3 is wider in width than the auxiliary wiring line SUW, and in a planar view, the auxiliary wiring line SUW is positioned in the edge of the third wiring line WS3.

The third wiring line WS3 is led from one side of the bending section CL to the other side of the bending section CL over the reinforcing film EZ, and sandwiched between the reinforcing film EZ and the flattening film 21 in the bending section CL. The auxiliary wiring line SUW passes through the penetration sections Nx, Nb, and Nc, and is sandwiched between the resin layer 12 and the reinforcing film EZ in the bending section CL. The resin layer 12, the reinforcing film EZ, and the flattening film 21 may be formed of the same organic material (e.g., polyimide).

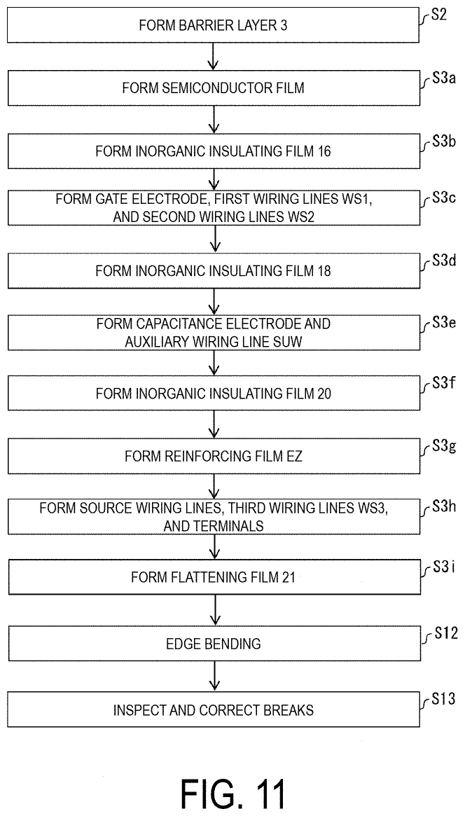

FIG. 11 is a flowchart illustrating an example of the formation of a TFT layer of the second embodiment. Subsequent to Step S1 in FIG. 1, the barrier layer 3 is formed at Step S2. At the next Step S3a, the semiconductor film 15 (see FIG. 2) is formed. At the next Step S3b, the inorganic insulating film 16 is formed. At the next Step S3c, the gate electrode, the first wiring lines WS1, and the second wiring lines WS2 are formed. At the next Step S3d, the inorganic insulating film 18 is formed. At the next Step S3e, the capacitance electrode CE (see FIG. 2) and the auxiliary wiring line SUW are formed. At the next Step S3f, the inorganic insulating film 20 is formed. At the next Step S3g, the reinforcing film EZ is formed. At the next Step S3h, the source wiring lines SH (see FIG. 2), the third wiring lines WS3, and the terminals TM are formed. At the next Step S3i, the flattening film 21 is formed (see FIG. 1 for subsequent processes onward). Note that the formation (patterning) of the penetration sections Nb and Nc may be performed in successive processes. Subsequently, as illustrated in FIG. 1, an edge bending is performed at Step S10, and inspection for breaks of the terminal wiring line is performed at Step S11.

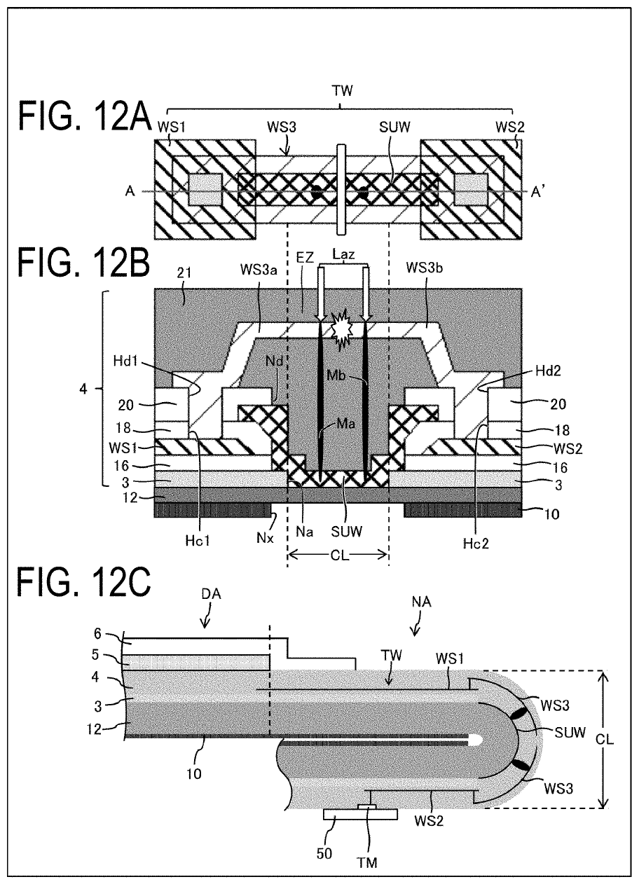

FIGS. 12A to 12C are views illustrating an example of correction of a broken line in the second embodiment; FIG. 12A is a top view, FIG. 12B is a cross-sectional view taken along line A-A′, and FIG. 12C is a cross-sectional view of a bending section. When breaks are found, and the third wiring line WS3 is divided by the breaks into the front portion WS3a and the rear portion WS3b, as illustrated in FIGS. 12A to 12C, the front portion WS3a is connected to the auxiliary wiring line SUW by the conductor Ma penetrating the reinforcing film EZ, and the rear portion WS3b is connected to the auxiliary wiring line SUW by the conductor Mb penetrating the reinforcing film EZ. The conductors Ma and Mb are formed by melting part of the front portion WS3a and part of the rear portion WS3b (sections corresponding to both sides of the breaks in a planar view) by the irradiation of laser Laz. In FIGS. 12A to 12C, the laser irradiation is performed from the upper side, but not limited to this. The laser irradiation may be performed from the penetration section Nx of the lower face film 10.

### Third Embodiment

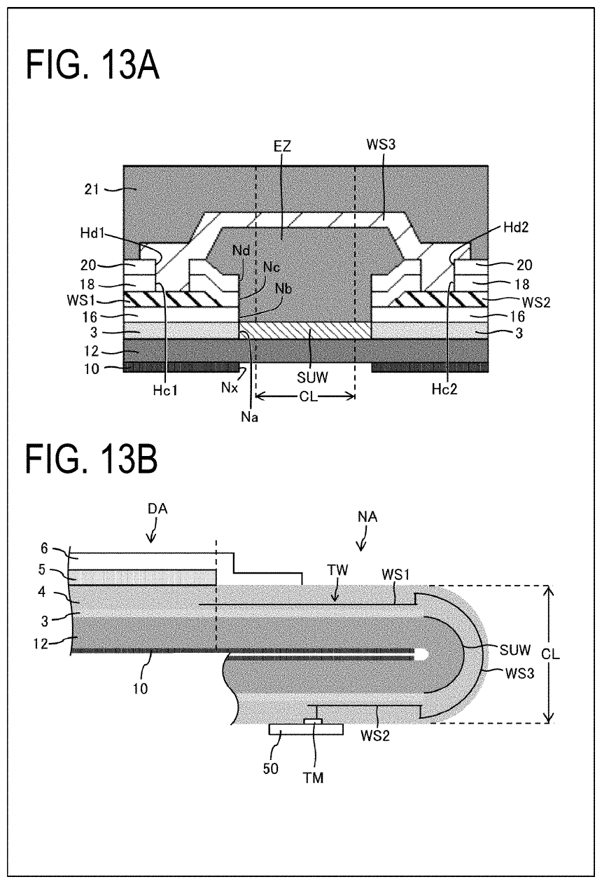

FIGS. 13A and 13B are cross-sectional views illustrating configuration of a non-display area of a third embodiment. As illustrated in FIGS. 13A and 13B, the lower face film 10, the barrier layer 3, and the inorganic insulating films 16, 18, and 20 are penetrated in the bending section CL of the non-display area NA. Specifically, the penetration section Nx is formed in the lower face film 10, the penetration section Na is formed in the barrier layer 3, the penetration section Nb is formed in the inorganic insulating film 16, the penetration section Nc is formed in the inorganic insulating film 18, the penetration section Nd is formed in the inorganic insulating film 20, and in a planar view, the penetration sections Nx, Nb, Nc, and Nd are aligned, and the bending section CL is positioned on the inside of the penetration sections Nx, Nb, Nc, and Nd. The reinforcing film EZ is provided in a space formed by the penetration sections Na, Nb, Nc, and Nd.

The terminal wiring line TW includes a first wiring line WS1 and a second wiring line WS2 positioned on both sides of the bending section CL, and a third wiring line WS3 that passes through the bending section CL and electrically connects to each of the first wiring line WS1 and the second wiring line WS2. The auxiliary wiring line SUW is superimposed on the third wiring line WS3 via the reinforcing film EZ (flexible insulating film) in the bending section CL.

Specifically, the first wiring line WS1 and the second wiring line WS2 are formed in the same layer as that of the gate electrodes GE (see FIG. 2) included in the TFT layer 4. The third wiring line WS3 is formed in the same layer as that of the source wiring lines SH (see FIG. 2) and the terminals TM included in the TFT layer 4, and has configuration in which an Al film is sandwiched between two Ti films, for example. The auxiliary wiring line SUW is formed in the same layer as that of the semiconductor film 15 of the TFT layer 4 and formed of an oxide semiconductor (e g., In—Ga—Zn—O semiconductor). The third wiring line WS3 and the auxiliary wiring line SUW extend in the same direction, and the third wiring line WS3 is wider in width than the auxiliary wiring line SUW, and in a planar view, the auxiliary wiring line SUW is positioned in the edge of the third wiring line WS3.

The third wiring line WS3 is led from one side of the bending section CL to the other side of the bending section CL over the reinforcing film EZ, and sandwiched between the reinforcing film EZ and the flattening film 21 in the bending section CL. The auxiliary wiring line SUW is formed filling the penetration section Na (of the barrier layer 3) and is sandwiched between the resin layer 12 and the reinforcing film EZ in the bending section CL. The resin layer 12, the reinforcing film EZ, and the flattening film 21 may be formed of the same organic material (e.g., polyimide).

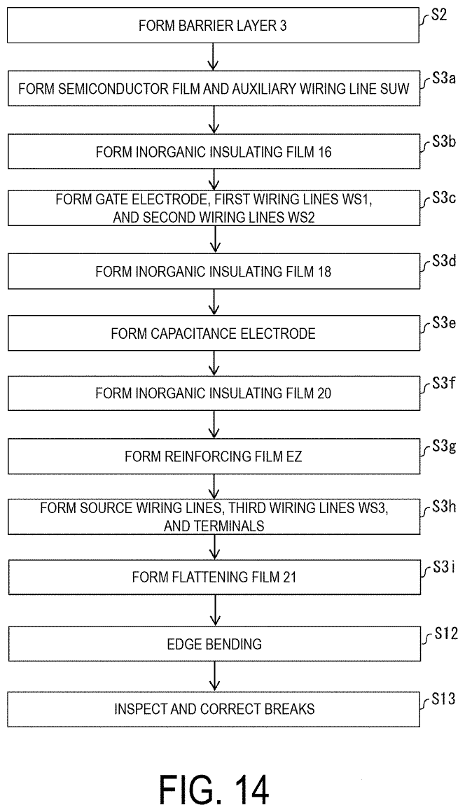

FIG. 14 is a flowchart illustrating an example of the formation of a TFT layer of the third embodiment. Subsequent to Step S1 in FIG. 1, the barrier layer 3 is formed at Step S2. At the next Step S3a, the semiconductor film 15 (see FIG. 2) and the auxiliary wiring line SUW is formed. Note that, as for the auxiliary wiring line SUW, a process (an anneal process, a plasma process, and the like) to increase the conductivity of the oxide semiconductor is performed. At the next Step S3b, the inorganic insulating film 16 is formed. At the next Step S3c, the gate electrode, the first wiring lines WS1, and the second wiring lines WS2 are formed. At the next Step S3d, the inorganic insulating film 18 is formed. At the next Step S3e, the capacitance electrode CE (see FIG. 2) is formed. At the next Step S3f, the inorganic insulating film 20 is formed. At the next Step S3g, the reinforcing film EZ is formed. At the next Step S3h, the source wiring lines SH (see FIG. 2), the third wiring lines WS3, and the terminals TM are formed. At the next Step S3i, the flattening film 21 is formed (see FIG. 1 for subsequent processes onward). Note that the formation (patterning) of the penetration sections Nb, Nc and Nd may be performed in successive processes using the auxiliary wiring line SUW as an edging stopper. Subsequently, as illustrated in FIG. 1, an edge bending is performed at Step S10, and inspection for breaks of the terminal wiring line is performed at Step S11.

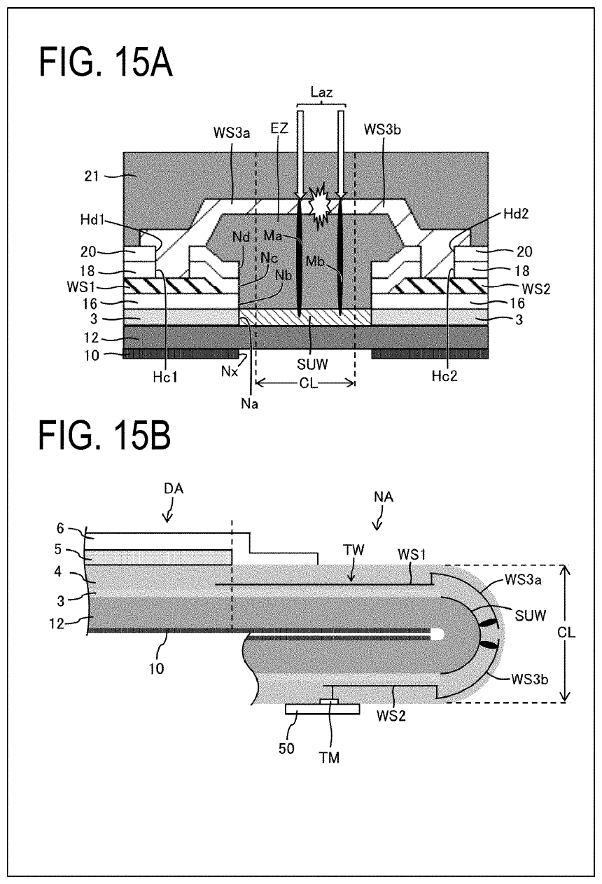

FIGS. 15A and 15B are views illustrating an example of correction of a broken line in the third embodiment. When breaks are found at Step S11, and the third wiring line WS3 is divided by the breaks into the front portion WS3a and the rear portion WS3b, as illustrated in FIGS. 15A and 15B, the front portion WS3a is connected to the auxiliary wiring line SUW by the conductor Ma penetrating the reinforcing film EZ, and the rear portion WS3b is connected to the auxiliary wiring line SUW by the conductor Mb penetrating the reinforcing film EZ. The conductors Ma and Mb are formed by melting part of the front portion WS3a and part of the rear portion WS3b (sections corresponding to both sides of the breaks in a planar view) by the irradiation of laser Laz. In FIGS. 15A and 15B, the laser irradiation is performed from the upper side, but not limited to this. The laser irradiation may be performed from the penetration section Nx of the lower face film 10.

### Supplement

An electro-optical element (an electro-optical element whose luminance and transmittance are controlled by an electric current) that is provided in the display device according to the present embodiment is not particularly limited. Examples of the display device according to the present embodiment include an organic electroluminescence (EL) display provided with the Organic Light Emitting Diode (OLED) as the electro-optical element, an inorganic EL display provided with an inorganic light emitting diode as the electro-optical element, and a Quantum dot Light Emitting Diode (QLED) display provided with a QLED as the electro-optical element.

### First Aspect

A display device including a resin layer, a TFT layer being an upper layer with respect to the resin layer, and a light-emitting element layer being an upper layer with respect to the TFT layer, a bending section being provided on a peripheral edge, includes at least one terminal wiring line configured to pass through the bending section and be connected to a terminal, and at least one auxiliary wiring line, wherein the at least one terminal wiring line includes a first wiring line and a second wiring line configured to be positioned on both sides of the bending section, a third wiring line configured to pass through the bending section and be electrically connected with each of the first wiring line and the second wiring line, and the at least one auxiliary wiring line is superimposed on the third wiring line via a flexible insulating film.

### Second Aspect

The display device according to the first aspect is such that, for example, a plurality of inorganic insulating films is included in the TFT layer, and the plurality of inorganic insulating films is penetrated in the bending section.

### Third Aspect

The display device according to the second aspect includes, for example, a barrier layer between the resin layer and the TFT layer, wherein the barrier layer is penetrated in the bending section.

### Fourth Aspect

The display device according to the third aspect is such that, for example, a reinforcing film is provided in a space formed by penetrating the barrier layer and the plurality of inorganic insulating films in the bending section.

### Fifth Aspect

The display device according to any one of the first to fourth aspects is such that, for example, the third wiring line is formed in a same layer as a layer of the terminal.

### Sixth Aspect

The display device according to the fifth aspect is such that, for example, the at least one auxiliary wiring line is formed in a same layer as a layer of a lower-side electrode included in the light-emitting element layer.

### Seventh Aspect

The display device according to the fifth aspect is such that, for example, the at least one auxiliary wiring line is formed on an upper layer with respect to a gate electrode and on a lower layer with respect to the terminal included in the TFT layer.

### Eight Aspect

The display device according to the fifth aspect is such that, for example, the at least one auxiliary wiring line is formed in a same layer as a layer of a semiconductor film included in the TFT layer.

### Ninth Aspect

The display device according to the fifth aspect is such that, for example, the first wiring line and the second wiring line are formed in a same layer as a layer of a gate electrode included in the TFT layer.

### Tenth Aspect

The display device according to the fourth aspect is such that, for example, the third wiring line is sandwiched between the reinforcing film and a flattening film serving as an underlayer of the light-emitting element layer in the bending section.

### Eleventh Aspect

The display device according to the sixth aspect is such that, for example, the at least one auxiliary wiring line is sandwiched between a flattening film serving as an underlayer of the light-emitting element layer and an insulating film formed in a same layer as a layer of an electrode edge cover of the light-emitting element layer in the bending section.

### Twelfth Aspect

The display device according to any one of the first to eleventh aspects is such that, for example, the light-emitting element layer is of a top-emitting type, and a bend at the bending section causes the terminal disposed on a lower face side to connect to an electronic circuit board.

### Thirteenth Aspect

The display device according to any one of the first to twelfth aspects is such that, for example, the third wiring line is divided by a break in the bending section into a front portion and a rear portion, and each of the front portion and the rear portion is connected to the at least one auxiliary wiring line by a conductor penetrating the flexible insulating film.

### Fourteenth Aspect

The display device according to any one of the seventh to ninth aspects is such that, for example, the at least one auxiliary wiring line and the resin layer are in contact with each other in the bending section.

### Fifteenth Aspect

The display device according to any one of the first to fourteenth aspects is such that, for example, the at least one terminal wiring line includes a plurality of terminal wiring lines, and the at least one auxiliary wiring line includes a plurality of auxiliary wiring lines, respectively, a terminal wiring line having been corrected and being electrically connected to the at least one auxiliary wiring line, and a terminal wiring line being not corrected and not electrically connected to the at least one auxiliary wiring line are included.

### Sixteenth Aspect

The display device according to the fifteenth aspect is such that, for example, on the terminal wiring line having been corrected, the first wiring line is connected to the second wiring line via the third wiring line and the at least one auxiliary wiring line.

### Seventeenth Aspect

A manufacturing method for a display device including a resin layer, a TFT layer being an upper layer with respect to the resin layer, and a light-emitting element layer being an upper layer with respect to the TFT layer, a bending section being provided on a peripheral edge, includes forming a first wiring line and a second wiring line configured to be positioned on both sides of the bending section, forming a third wiring line configured to pass through the bending section and be electrically connected with each of the first wiring line and the second wiring line, and forming an auxiliary wiring line configured to be superimposed on the third wiring line via a flexible insulating film in the bending section.

### Eighteenth Aspect

The manufacturing method for the display device according to the fourteenth aspect includes, for example, connecting, when the third wiring line is divided by a break in the bending section into a front portion and a rear portion, each of the front portion and the rear portion to the auxiliary wiring line by a conductor penetrating the flexible insulating film.

### Nineteenth Aspect

The manufacturing method for the display device according to the eighteenth aspect includes, for example, forming the conductor by melting the third wiring line or the auxiliary wiring line with irradiation of laser.

### Twentieth Aspect

A manufacturing apparatus for a display device including a resin layer, a TFT layer being an upper layer with respect to the resin layer, and a light-emitting element layer being an upper layer with respect to the TFT layer, a bending section being provided on a peripheral edge, is configured to execute forming a first wiring line and a second wiring line configured to be positioned on both sides of the bending section, forming a third wiring line configured to pass through the bending section and be electrically connected with each of the first wiring line and the second wiring line, and forming an auxiliary wiring line configured to be superimposed on the third wiring line via a flexible insulating film in the bending section.

### REFERENCE SIGNS LIST

2 Display device
3 Barrier layer
4 TFT layer
5 Light emitting-element layer
6 Sealing layer
12 Resin layer
16, 18, 20 Inorganic insulating film
21 Flattening film
23 Bank (Electrode edge cover)
23z Organic insulating film
24 EL layer
70 Display device manufacturing apparatus
EZ Reinforcing film
TM Terminal
TW Terminal wiring line
SUW Auxiliary wiring line
WS1 TO WS3 First wiring line to Third wiring line

1. A display device including a resin layer, a TFT layer being an upper layer with respect to the resin layer, and a light-emitting element layer being an upper layer with respect to the TFT layer, a bending section being provided on a peripheral edge, comprising:
at least one terminal wiring line configured to pass through the bending section and be connected to a terminal; and
at least one auxiliary wiring line,
wherein the at least one terminal wiring line includes
a first wiring line and a second wiring line configured to be positioned on both sides of the bending section,
a third wiring line configured to pass through the bending section and be electrically connected with each of the first wiring line and the second wiring line, and
the at least one auxiliary wiring line is superimposed on the third wiring line via a flexible insulating film.

2. The display device according to claim 1,
wherein a plurality of inorganic insulating films is included in the TFT layer, and
the plurality of inorganic insulating films is penetrated in the bending section.

3. The display device according to claim 2, further comprising:
a barrier layer between the resin layer and the TFT layer,
wherein the barrier layer is penetrated in the bending section.

4. The display device according to claim 3,
wherein a reinforcing film is provided in a space formed by penetrating the barrier layer and the plurality of inorganic insulating films in the bending section.

5. The display device according to claim 1,
wherein the third wiring line is formed in a same layer as a layer of the terminal.

6. The display device according to claim 5,
wherein the at least one auxiliary wiring line is formed in a same layer as a layer of a lower-side electrode included in the light-emitting element layer.

7. The display device according to claim 5,
wherein the at least one auxiliary wiring line is formed on an upper layer with respect to a gate electrode and on a lower layer with respect to the terminal included in the TFT layer.

8. The display device according to claim 5,
wherein the at least one auxiliary wiring line is formed in a same layer as a layer of a semiconductor film included in the TFT layer.

9. The display device according to claim 5,
wherein the first wiring line and the second wiring line are formed in a same layer as a layer of a gate electrode included in the TFT layer.

10. The display device according to claim 4,
wherein the third wiring line is sandwiched between the reinforcing film and a flattening film serving as an underlayer of the light-emitting element layer in the bending section.

11. The display device according to claim 6,
wherein the at least one auxiliary wiring line is sandwiched between a flattening film serving as an underlayer of the light-emitting element layer and an insulating film formed in a same layer as a layer of an electrode edge cover of the light-emitting element layer in the bending section.

12. The display device according to claim 1,
wherein the light-emitting element layer is of a top-emitting type, and
a bend at the bending section causes the terminal disposed on a lower face side to connect to an electronic circuit board.

13. The display device according to claim 1,
wherein the third wiring line is divided by a break in the bending section into a front portion and a rear portion, and
each of the front portion and the rear portion is connected to the at least one auxiliary wiring line by a conductor penetrating the flexible insulating film.

14. The display device according to claim 7,
wherein the at least one auxiliary wiring line and the resin layer are in contact with each other in the bending section.

15. The display device according to claim 1,
wherein the at least one terminal wiring line includes a plurality of terminal wiring lines, and the at least one auxiliary wiring line includes a plurality of auxiliary wiring lines, respectively,
a terminal wiring line having been corrected and being electrically connected to the at least one auxiliary wiring line, and a terminal wiring line being not corrected and not electrically connected to the at least one auxiliary wiring line are included.

16. The display device according to claim 15,
wherein, on the terminal wiring line having been corrected, the first wiring line is connected to the second wiring line via the third wiring line and the at least one auxiliary wiring line.

17. A manufacturing method for a display device including a resin layer, a TFT layer being an upper layer with respect to the resin layer, and a light-emitting element layer being an upper layer with respect to the TFT layer, a bending section being provided on a peripheral edge, comprising:
forming a first wiring line and a second wiring line configured to be positioned on both sides of the bending section;
forming a third wiring line configured to pass through the bending section and be electrically connected with each of the first wiring line and the second wiring line; and
forming an auxiliary wiring line configured to be superimposed on the third wiring line via a flexible insulating film in the bending section.

18. The manufacturing method for the display device according to claim 14, further comprising:
connecting, when the third wiring line is divided by a break in the bending section into a front portion and a rear portion, each of the front portion and the rear portion to the auxiliary wiring line by a conductor penetrating the flexible insulating film.

19. The manufacturing method for the display device according to claim 18, further comprising:
forming the conductor by melting the third wiring line or the auxiliary wiring line with irradiation of laser.

20. A manufacturing apparatus for a display device including a resin layer, a TFT layer being an upper layer with respect to the resin layer, and a light-emitting element layer being an upper layer with respect to the TFT layer, a bending section being provided on a peripheral edge, the manufacturing apparatus being configured to execute:
forming a first wiring line and a second wiring line configured to be positioned on both sides of the bending section;
forming a third wiring line configured to pass through the bending section and be electrically connected with each of the first wiring line and the second wiring line; and
forming an auxiliary wiring line configured to be superimposed on the third wiring line via a flexible insulating film in the bending section.
